(19) United States
(12) Patent Application Publication
(10) Pub. No.: US 2022/0127459 A1
(43) Pub. Date: Apr. 28, 2022

(54) Dielectric Film-Forming Composition

(71) Applicant: Fujifilm Electronic Materials U.S.A., Inc., N. Kingstown, RI (US)

(72) Inventors: Binod B. De, Attleboro, MA (US); Raj Sakamuri, Sharon, MA (US); Sanjay Malik, Attleboro, MA (US); Stephanie Dilocker, Attleboro, MA (US); William A. Reinerth, Riverside, RI (US)

(21) Appl. No.: 17/498,813

(22) Filed: Oct. 12, 2021

Related U.S. Application Data
(60) Provisional application No. 63/094,960, filed on Oct. 22, 2020.

(51) Int. Cl. C08L 79/08; C08K 5/315; C08K 5/3475; G03F 7/039; G03F 7/20; G03F 7/16; G03F 7/32; G03F 7/40

(52) U.S. Cl. CPC C08L 79/08; C08K 5/315; C08K 5/3475; G03F 7/40; G03F 7/2004; G03F 7/162; G03F 7/325; G03F 7/0392

(57) ABSTRACT

This disclosure relates to a dielectric film-forming composition that includes (a) at least one cyanate ester compound, the at least one cyanate ester compound containing at least two cyanate groups; and (b) at least one dielectric polymer including a polybenzoxazoie precursor polymer, a polyimide precursor polymer, or a fully imidized polyimide polymer.

### CROSS-REFERENCE TO RELATED APPLICATION

The present application claims priority to U.S. Provisional Application Ser. No. 63/094,960, filed on Oct. 22, 2020, the contents of which are hereby incorporated by reference in their entirety.

### BACKGROUND OF THE DISCLOSURE

Dielectric material requirements for semiconductor packaging applications are continuously evolving. The trend in electronic packaging continues to be towards faster processing speeds, increased complexity and higher packing density while maintaining high level of reliability. Current and future packaging architectures include up to 10 redistribution layers and ultra-small features sizes to support high packing density. The insulating dielectric material thickness is significantly reduced to accommodate multiple redistribution layers in thin and small form factor. Organic dielectric materials with low thermal shrinkage and low cure temperature are suitable for such applications. For example, polyimide and polybenzoxazole precursors can be cured at relatively low cure temperature (200 to 300° C.) in the presence of a suitable catalyst. However, these materials suffer from appreciable shrinkage during the cure step. Moreover, the resulting cured films have glass-transition temperature in the range of 200 to 230° C. which is significantly lower than the solder paste reflow temperature of 260° C. This results in excessive flow of the dielectric film leading to delamination and changes in the critical dimension of patterned structures.

### SUMMARY OF THE DISCLOSURE

This disclosure is based on the unexpected discovery that certain dielectric film-forming composition can form dielectric films that possess a relatively low film shrinkage, a relatively low dielectric constant and/or dissipation factor, and a relatively high glass transition temperature (Tg) (e.g., having a Tg higher than the solder paste reflow temperature (e.g., 260° C.)).

In one aspect, the present disclosure features a dielectric film-forming composition that includes a) at least one cyanate ester compound, the at least one cyanate ester compound containing at least two cyanate groups; and b) at least one dielectric polymer comprising a polybenzoxazole precursor polymer, a polyimide precursor polymer, or a fully imidized polyimide polymer.

In another aspect, the present disclosure features a dry film that includes a carrier substrate, and a dielectric film supported by the carrier substrate, in which the film is prepared from the dielectric film-forming composition described herein.

In another aspect, the present disclosure features a process for depositing a metal layer. The process includes a) depositing the dielectric film-forming composition described herein on a substrate to form a dielectric film; b) exposing the dielectric film to radiation or heat or a combination of radiation or heat; c) patterning the dielectric film to form a patterned dielectric film having openings; d) optionally depositing a seed layer on the patterned dielectric film; and e) depositing a metal layer in at least one opening in the patterned dielectric film.

In another aspect, the present disclosure features a process for forming a dielectric film on a substrate. The process includes a) providing a substrate containing copper conducting metal wire structures that form a network of lines and interconnects on the substrate; b) depositing the dielectric film-forming composition described herein on the substrate to form a dielectric film; and c) exposing the dielectric film to radiation or heat or a combination of radiation and heat.

In yet another aspect, the present disclosure features a three dimensional object prepared by the process described herein. In some embodiments, the object includes the dielectric film in at least two or three stacks.

### DETAILED DESCRIPTION OF THE DISCLOSURE

In some embodiments, this disclosure relates to a dielectric film-forming composition (e.g., a photosensitive or non-photosensitive dielectric film-forming composition) that includes;

a) at least one cyanate ester compound having at least two cyanate groups (i.e., in one molecule); and

b) at least one dielectric polymer containing a polybenzoxazole precursor polymer, a polyimide precursor polymer, or a fully imidized polyimide polymer.

The dielectric film-forming composition described herein can be either photosensitive or non-photosensitive. In some embodiments, when the dielectric film-forming composition is photosensitive, the composition can form a film that is capable of generating a solubility change in a developer upon exposure to high energy radiation (such as electron beams, ultraviolet light, and X-ray). For example, the composition can form a negative photosensitive film that can be crosslinked in the exposed area, which has a decreased solubility in a developer. In such embodiments, the dielectric film-forming composition can include at least one crosslinker and/or at least one catalyst (e.g., a free radical initiator) for inducing crosslinking reactions of the crosslinker, which are in addition to the cyanate ester compound and the dielectric polymer described above.

In some embodiments, when the dielectric film-forming composition is non-photosensitive, the composition does not have solubility change in a developer upon exposure to high energy radiation. In such embodiments, the composition may not include any crosslinker and/or catalyst. In some embodiments, such a composition can include at least one cyanate curing catalyst (e.g., a metal salt) for facilitating the cyanate ester compound to form an interpenetrating network, which can be different from a catalyst for inducing crosslinking reactions of a crosslinker.

In some embodiments, the dielectric film-forming composition described herein can include at least one (e.g., two, three, or four) cyanate ester compound. Without wishing to be bound by theory, it is believed that the cyanate ester compound can be cyclized and/or crosslinked thermally (e.g., with or without a catalyst) to form an interpenetrating network with the dielectric polymer. Further, without wishing to be bound by theory, it is believed that including a cyanate ester compound in the dielectric film-forming composition described herein can lower the dielectric constant (K) and/or dissipation factor (DF) of the film formed from the composition.

In some embodiments, the cyanate ester compounds have Structure (I):

A-(O—C≡N)ₘ (I),

in which m is an integer of at least 2 (i.e., m≥2) and A is a divalent organic group containing a substituted or unsubstituted aromatic group (e.g., the cyanate ester groups —O—C≡N are directly bonded to the substituted or unsubstituted aromatic group). In some embodiments, the aromatic organic group can include aryl and heteroaryl groups. The term “aryl” used herein refers to a hydrocarbon moiety having one or more aromatic rings. Examples of aryl moieties include phenyl (Ph), phenylene, naphthyl, naphthylene, pyrenyl, anthryl; and phenanthryl. The term “heteroaryl” used herein refers to a moiety having one or more aromatic rings that contain at least one heteroatom (e.g., N, O, or S). Examples of heteroaryl moieties include furyl, furylene, fluorenyl, pyrrolyl, thienyl, oxazolyl, imidazolyl, thiazolyl, pyridinyl, pyrimidinyl, quinazolinyl, quinolyl, isoquinolyl and indolyl.

As used herein, possible substituents on a substituted group (e.g., a substituted alkyl; alkenyl; alkylene, cycloalkyl, cycloalkylene, aryl, arylalkyl, or heteroaryl group) or a substituted compound include C₁-C₁₀ alkyl, C₂-C₁₀ alkenyl, C₂-C₁₀ alkynyl, C₃-C₂₀ cycloalkyl, C₃-C₂₀ cycloalkenyl, C₃-C₂₀ heterocycloalkyl, C₃-C₂₀ heterocycloalkenyl, C₁-C₁₀ alkoxy, aryl, aryloxy, heteroaryl, heteroaryloxy, amino, C₁-C₁₀ alkylamino, C₁-C₂₀ dialkylamino, arylamino, diarylamino, hydroxyl, halogen, thio, alkylthio, arylthio, alkylsulfonyl, arylsulfonyl, acylamino, aminoacyl, aminothioacyl, amidino, guanidine, ureido, cyano, nitro, acyl, thioacyl, acyloxy, carboxyl, and carboxylic ester.

In some embodiments, A is a substituted or unsubstituted monomeric or oligomeric polycyclic aromatic or heterocyclic aromatic organic group in which the cyanate ester groups are directly bonded to said aromatic organic group.

In some embodiments, the cyanate ester compounds of Structure (I) can be those of Structure (II):

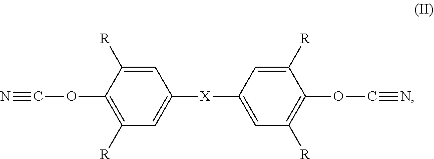

in which R is a hydrogen atom, a C₁-C₃ alkyl group, a fully or partially halogen (e.g., F, CI, Br, or I) substituted C₁-C₃ alkyl group (e.g., substituted by 1, 2, or 3 halogen), or a halogen atom; and X is a single bond, —O—, —S—, —(C═O)—, —(C═O)—O—, —O—(C═O)—, —(S═O)—, —(SO₂)—, —CH₂CH₂—O—, a substituted or unsubstituted C₁-C₁₀ alkylene, a fluoro substituted (partially or fully) C₁-C₄ alkylene (e.g., substituted by 1, 2, or 3 fluoro), a substituted or unsubstituted C₃-C₁₀ cycloalkylene, or one of the following groups:

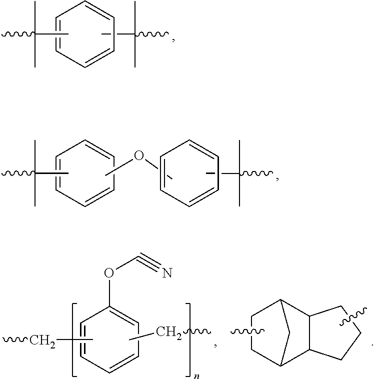

In some embodiments, the cyanate ester compounds can have Structure (III):

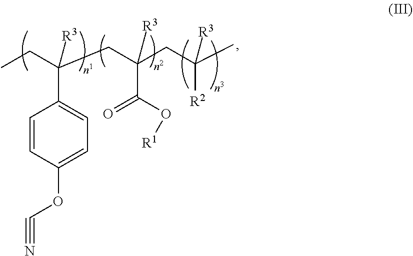

in which n₁ is an integer of at least 2 (i.e., n₁≥2), n₂ and n₃ are independently 0 or an integer from 1 to 100, R¹ is an acid sensitive substituted alkyl, silyl, aryl, or arylalkyl group (e.g., tert-butyl, methoxymethyl, or dimethylphenyl), R² is a substituted or unsubstituted C₁-C₁₀ alkyl, a substituted or unsubstituted C₃-C₁₀ cycloalkyl, a substituted or unsubstituted aryl group, or a —(C═O)—OR⁴ group where R⁴ is a non-acid sensitive substituted alkyl or arylalkyl group; and R³ is a substituted or unsubstituted C₁-C₁₀ alkyl, or a fluoro substituted (e.g., partially or fully) C₁-C₄ alkyl.

Specific examples of suitable cyanate ester compounds include 2-bis(4-cyanatophenyl)propane, hexafluorobisphenol A dicyanate, bis(4-cyanate3,5 dimethylphenyl)methane, 1,3-bis(4-cyanatephenyl-1-(methylethylidene))benzene, bis(4-cyanatephenyl)thioether, and bis(4-cyanatephenyl)ether; a polyfunctional cyanate ester derived from a phenol novolac, cresol novolac, or dicyclopentadiene structure-containing phenol resin, or the like. Other examples of cyanate ester compounds have been described in, e.g., U.S. Pat. Nos. 3,595,900; 4,894,414, and 4,785,034, the contents of which are hereby incorporated by reference. In some embodiments, two or more cyanate ester compounds can be used in the dielectric film-forming composition described herein.

In some embodiments, the dielectric film-forming composition described herein preferably includes two or more cyanate ester compounds.

In general, the weight average molecular weight of the cyanate ester resin is not particularly limited. In some embodiments, the cyanate ester compound can have a weight average molecular weight ranging from at least about 500 Daltons (e.g., at least about 600 Daltons or at least about 1,000 Daltons) to at most about 4,500 (e.g., at most about 4,000 Daltons, or at most about 3,000 Daltons).

In some embodiments, the amount of the at least one cyanate ester compound is at least about 2 weight % (e.g., at least about 5 weight %, at least about 10 weight %, at least about 15 weight %, or at least 20 weight %) and/or at most about 55 weight % (e.g., at most about 50 weight %, at most about 45 weight %, at most about 40 weight %, at most about 35 weight %, at most about 30 weight %, or at most about 25 weight %) of the total weight of the dielectric film-forming composition described herein.

In some embodiments, the dielectric film-forming composition described herein can include at least one (e.g., two, three, or four) dielectric polymer selected from the group consisting of polybenzoxazole precursor polymers, polyimide precursor polymers, and fully imidized polyimide polymers. In some embodiments, the dielectric polymer is a fully imidized polyimide polymer. The fully imidized polyimide polymer mentioned herein is at least about 90% (e.g., at least about 95%, at least about 98%, at least about 99%, or about 100%) imidized. The preferred fully imidized polyimide polymers are those without having any polymerizing moiety attached to the polymer. Without wishing to be bound by theory, it is believed that including the above polymers in the dielectric film-forming composition described herein can increase the glass transition temperature, decrease the thermal shrinkage, and improve the mechanical properties of the film formed by the composition.

In some embodiment, the dielectric polymer can include one or more (e.g., two, three, or four) cross-linkable groups such that the dielectric polymer can be crosslinked either by itself or with a crosslinker (such as the reactive functional compound described herein), Examples of cross-linkable groups include are an end group containing a double or triple bond or a side group attached to the main chain of polymer that contains a double or triple bond).

In some embodiments, the weight average molecular weight of the dielectric polymer is at least about 20,000 Daltons (e.g., at least about 25,000 Daltons, at least about 30,000 Daltons, at least about 35,000 Daltons, at least about 40,000 Daltons, at least about 45,000 Daltons, at least about 50,000 Daltons, or at least about 55,000 Daltons) and/or at most about 100,000 Daltons (e.g., at most about 95,000 Daltons, at most about 90,000 Daltons, at most about 85,000 Daltons, at most about 80,000 Daltons, at most about 75,000 Daltons, at most about 70,000 Daltons, at most about 65,000 Daltons, or at most about 60,000 Daltons).

Methods to synthesize polybenzoxazole precursor polymers are known to those skilled in the art. Examples of such methods are disclosed in, e.g., U.S. Pat. Nos. 6,143,467, 7,195,849, 7,129,011, and 9,519,216, the contents of which are hereby incorporated by reference.

Methods to synthesize polyimide precursor polymer (e.g. polyamic acid ester polymers) are also known to those skilled in the art. Examples of such methods are disclosed in, e.g., U.S. Pat. Nos. 4,040,831, 4,548,891, U.S. Pat. No 5, 834,581 and U.S. Pat. No. 6,511,789, the contents of which are hereby incorporated by reference.

Methods to synthesize polyimide polymers (e.g., fully imidized polyimide polymers) are known to those skilled in the art. Examples of such methods are disclosed in, e.g., U.S. Pat. No. 9,617,386, and US Application Publication Nos. 20040265731, 20040235992, and 2007083016, the contents of which are hereby incorporated by reference.

In some embodiments, the amount of the dielectric polymer is at least about 2 weight % (e.g., at least about 5 weight %, at least about 10 weight %, at least about 15 weight %, or at least about 20 weight %) and/or at most or about 55 weight % (e.g., at most about 50 weight %, at most about 45 weight %, at most about 40 weight %, at most about 35 weight %, at most about 30 weight %, or at most about 25 weight %) of the total weight of the dielectric film-forming composition.

In some embodiments, the dielectric film-forming composition described herein can further include at least one (e.g., two, three, or four) solvent (e.g., an organic solvent).

Examples of organic solvents include, but are not limited to, alkylene carbonates such as ethylene carbonate, propylene carbonate, butylene carbonate, and glycerine carbonate; lactones such as gamma-butyrolactone, ε-caprolactone, γ-caprolactone and δ-valerolactone; cycloketones such as cyclopentanone and cyclohexanone; linear ketones such as methyl ethyl ketone (MEK) and methyl isobutyl ketone (MIBK); esters such as n-butyl acetate; ester alcohol such as ethyl lactate; ether alcohols such as tetrahydrofurfuryl alcohol; glycol esters such as propylene glycol methyl ether acetate; glycol ethers such as propylene glycol methyl ether (PGME); cyclic ethers such as tetrahydrofuran (THF); and pyrrolidones such as N-methyl-2-pyrrolidone.

In a preferred embodiment, the solvent of the dielectric film-forming composition contains alkylene carbonates such as ethylene carbonate, propylene carbonate, butylene carbonate, glycerine carbonate, or a combination thereof. In some embodiments, the amount of alkylene carbonate in a solvent mixture is at least about 20% (e.g., at least about 30%, at least about 40%, at least about 50%, at least about 60%, at least about 70%, at least 80%, or at least about 90%) of the dielectric film-forming composition. Without wishing to be bound by theory, it is believed that a carbonate solvent (e.g., ethylene carbonate, propylene carbonate, butylene carbonate or glycerine carbonate) can facilitate the formation of a dielectric film with a planarized surface (e.g., the difference in the highest and lowest points on a top surface of the dielectric film is less than about 2 microns).

In some embodiments, the amount of the solvent is at least about 20 weight % (e.g., at least about 25 weight %, at least about 30 weight %, at least about 35 weight %, at least about 40 weight %, at least about 45 weight %, at least about 50 weight %, at least about 55 weight %, at least about 60 weight %, or at least about 65 weight %) and/or at most about 98 weight % (e.g., at most about 95 weight %, at most about 90 weight %, at most about 85 weight %, at most about 80 weight %, at most about 75 weight %, at most about 70 weight %, or at most about 60 weight %) of the total weight of the dielectric film-forming composition.

In some embodiments, the dielectric film-forming composition of this disclosure can optionally include at least one (e.g., two, three, or four) catalyst (e.g., an initiator). In some embodiments, depending on the type of the catalyst used, the catalyst is capable of cyclizing and/or crosslinking of cyanate ester, or inducing crosslinking or polymerization reactions when exposed to heat (e.g., a thermoinitiator) and/or a source of radiation (e.g., a photoinitiator such as free radical photoinitiator).

In some embodiments, the dielectric film-forming composition described herein can optionally include at least one (e.g., two, three, or four) cyanate curing catalyst to facilitate the curing of the cyanate ester compound (e.g., to form an interpenetrating network) and/or reduce curing temperature of dielectric film. The cyanate curing catalyst can be in either a photosensitive dielectric film-forming composition or a non-photosensitive dielectric film-forming composition.

In some embodiments, the cyanate curing catalyst can be selected from the group consisting of metal carboxylate salts and metal acetylacetonate salts. The metal in the metal carboxylate salts and metal acetylacetonate salts can be selected from the group consisting of zinc, copper, manganese, cobalt, iron, nickel, aluminum, titanium, zirconium, and mixtures thereof. Examples of cyanate curing catalysts include metal salts such as zirconyl dimethacrylate, zinc octanoate, zinc naphthenate, cobalt naphthenate, copper naphthenate, and acetylacetone iron; phenol compounds such as octylphenol and nonylphenol; alcohols such as 1-butanol and 2-ethylhexanol; imidazole compounds such as 2-methylimidazole, 2-ethyl-4-methylimidazole, 2-phenylimidazole, 1-cyanoethyl-2-phenylimidazole, 1-cyanoethyl-2-ethyl-4-methylimidazole, 2-phenyl-4,5-dihydroxymethylimidazole, and 2-phenyl-4-methyl-5-hydroxymethylimidazole; amine compounds such as dicyandiamide, benzyldimethylamine, and 4-methyl-N,N-dimethylbenzylamine; phosphorus compounds such as phosphine compounds and phosphonium compounds; epoxy-imidazole adduct compounds; and peroxides such as benzoyl peroxide, p-chlorobenzoyl peroxide, di-t-butyl peroxide, diisopropyl peroxycarbonate, and di-2-ethylhexyl peroxycarbonate. These catalysts are commercially available. Examples of the commercially available catalysts include Amicure PN-23 (trade name, manufactured by Ajinomoto Fine-Techno Co., Inc.), Novacure HX-3721 (trade name, manufactured by Asahi Kasei Corporation.), and Fujicure FX-1000 (trade name, manufactured by Fuji Kasei Kogyo Co., Ltd.). One or a combination of two or more of these catalysts can be used in the composition described herein. Other examples of such catalysts have been described in, e.g., U.S. Patent Application number 2018/0105488 and U.S. Pat. No. 9,822,226, the contents of which are hereby incorporated by reference.

In some embodiments (e.g., in a photosensitive composition), the dielectric film-forming composition described herein can optionally include at least one (e.g., two, three, or four) photoinitiator to facilitate crosslinking reactions of a crosslinker (e.g., a reactive functional compound described herein) or crosslinking reactions between a crosslinker and the dielectric polymer (e.g., when it includes a cross-linkable group). Specific examples of photoinitiators include, but are not limited to, 1,8-octanedione, 1,8-bis[9-(2-ethylhexyl)-6-nitro-9H-carbazol-3-yl]-1,8-bis(O-acetyloxime), 2-hydroxy-2-methyl-1-phenylpropan-1-one, 1-hydroxycyclohexyl phenyl ketone (Irgacure 184 from BASF), a blend of 1-hydroxycyclohexylphenylketone and benzophenone (Irgacure 500 from BASF), 2,4,4-trimethylpentyl phosphine oxide (Irgacure 1800, 1850, and 1700 from BASF), 2,2-dimethoxyl-2-acetophenone (Irgacure 651 from BASF), bis(2,4,6-trimethyl benzoyl)phenyl phosphine oxide (Irgacure 819 from BASF), 2-methyl-1-[4-(methylthio)phenyl]-2-morphorinopropane-1-one (Irgacure 907 from BASF), (2,4,6-trimethylbenzoyl)diphenyl phosphine oxide (Lucerin TPO from BASF), 2-(Benzoyloxyimino)-1-[4-(phenylthio)phenyl]-1-octanone (Irgacure OXE-01 from BASF), 1-[9-ethyl-6-(2-methylbenzoyl)-9H-carbazol-3-yl]ethanone, 1-(O-acetyloxime) (Irgacure OXE-2 from BASF), ethoxy(2,4,6-trimethylbenzoyl)phenyl phosphine oxide (Lucerin TPO-L from BASF), a blend of phosphine oxide, hydroxy ketone and a benzophenone derivative (ESACURE KTO46 from Arkema), 2-hydroxy-2-methyl-1-phenylpropane-1-one (Darocur 1173 from Merck), NCI-831 (ADEKA Corp.), NCI-930 (ADEKA Corp.), N-1919 (ADEKA Corp.), benzophenone, 2-chlorothioxanthone, 2-methylthioxanthone, 2-isopropylthioxanthone, benzodimethyl ketal, 1,1,1-trichloroacetophenone, diethoxyacetophenone, m-chloroacetophenone, propiophenone, anthraquinone, dibenzosuberone and the like.

In some embodiments, a photosensitizer can be used in the dielectric film-forming composition where the photosensitizer can absorb light in the wavelength range of 193 to 405 nm. Examples of photosensitizers include, but are not limited to, 9-anthracenemethanol, acenaphthylene, thioxanthone, methyl-2-naphthyl ketone, 4-acetylbiphenyl, and 1,2-benzofluorene.

Specific examples of thermal initiators include, but are not limited to, benzoyl peroxide, cyclohexanone peroxide, lauroyl peroxide, tert-amyl peroxybenzoate, tert-butyl hydroperoxide, di(tert-butyl)peroxide, dicumyl peroxide, cumene hydroperoxide, succinic acid peroxide, di(n-propyl)peroxydicarbonate, 2,2-azobis(isobutyronitrile), 2,2-azobis(2,4-dimethylvaleronitrile), dimethyl-2,2-azobisisobutyrate, 4,4-azobis(4-cyanopentanoic acid), azobiscyclohexanecarbonitrile, 2,2-azobis(2-methylbutyronitrile) and the like.

In some embodiments, the amount of the catalyst is at least about 0.2 weight % (e.g., at least about 0.5 weight %, at least about 0.8 weight %, at least about 1.0 weight %, or at least about 1.5 weight %) and/or at most about 3.0 weight % (e.g., at most about 2.8 weight %, at most about 2.6 weight %, at most about 2.3 weight %, or at most about 2.0 weight %) of the total weight of the dielectric film-forming composition.

In some embodiments, the dielectric film-forming composition described herein can optionally include at least one (e.g., two, three, or four) reactive functional compound. In some embodiments, the reactive functional compound can include at least two functional groups (e.g., (meth)acrylate, alkenyl, or alkynyl groups). In some embodiments, the functional groups on the reactive functional compound are capable of reacting with another molecule of the reactive functional compound or with the dielectric polymer (e.g., when it includes a cross-linkable group). Without wishing to be bound by theory, it is believed that the reactive functional compound can be used as a crosslinker in a photosensitive composition to form a negative photosensitive film.

In some embodiments, the reactive functional compound is a compound containing at least two (meth)acrylate groups. As used herein, the term “(meth)acrylate” include both acrylates and methacrylates. Examples of such compounds include, but are not limited to, 1,3-butylene glycol di(meth)acrylate, 1,4-butanediol di(meth)acrylate, 1,5-pentanediol di(meth)acrylate, 1,6-hexanediol di(meth)acrylate, 1,9-nonanediol di(meth)acrylate, 1,10-decanediol di(meth)acrylate, 1,12-dodecanediol di(meth)acrylate, tetraethyleneglycol di(meth)acrylate, cyclohexane dimethanol di(meth)acrylate, polyethylene glycol di(meth)acrylate, ethylene glycol di(meth)acrylate, polyethylene glycol di(meth)acrylate, diurethane di(meth)acrylate, 1,4-phenylene di(meth)acrylate, 2,2-bis[4-(2-hydroxy-3-methacryloxypropoxy)phenyl]propane, bis(2-hydroxyethyl)-isocyanurate di(meth)acrylate, neopentyl glycol di(meth)acrylate, tricyclodecane dimethanol di(meth)acrylate, propoxylated (3) glycerol tri(meth)acrylate, pentaerythritol tetra(meth)acrylate, pentaerythritol tri(meth)acrylate, dipentaerythritol penta-/hexa-(meth)acrylate, isocyanurate tri(meth)acrylate, ethoxylated glycerine tri(meth)acrylate, trimethylol propane tri(meth)acrylate, ditrimethylol propane tetra(meth)acrylate, ethoxylated pentaerythritol tetra(meth)acrylate, tetramethylol methane tetra(meth)acrylate, 1,2,4-butanetriol tri(meth)acrylate, diglycerol tri(meth)acrylate, trimethylol propane ethoxylate tri(meth)acrylate, trimethylol propane polyethoxylate tri(meth)acrylate, tetramethylolmethane tetra(meth)acrylate and tris(2-hydroxyethyl)isocyanurate triacrylate. The preferred reactive functional compounds are di(meth)acrylate of an unsubstituted/substituted linear, branch or cyclic C₁-C₁₀ alkyl or an unsubstituted/substituted aromatic group. The reactive functional compound can be used alone or combination of two or more kinds thereof in the dielectric film-forming composition described herein.

In some embodiments, the amount of the at least one reactive functional compound is at least about 1 weight % (e.g., at least about 2 weight %, at least about 3 weight %, at least about 4 weight %, or at least 5 weight %) and/or at most about 25 weight % (e.g., at most about 20 weight %, at most about 15 weight %, at most about 10 weight %, or at most about 8 weight %)) of the total weight of the dielectric film-forming composition.

In some embodiments, the dielectric film-forming composition can optionally contain at least one mono (meth)acrylate containing compound. In some embodiment, the at least one mono (meth)acrylate containing compound is selected from the group consisting of bornyl acrylate, isobornyl acrylate, dicyclopentenyloxyethyl acrylate, dicyclopentenylacrylate, dicyclopentenyloxyethyl methacrylate, dicyclopentenyl methacrylate, bicyclo[2.2.2]oct-5-en-2-yl acrylate, 2-[(bicyclo[2.2.2]oct-5-en-2-yl)oxy]ethyl acrylate, 3a,4,5,6,7,7a-hexahydro-1H-4,7-ethanoinden-6-yl acrylate, 2-[(3a,4,5,6,7,7a-hexahydro-1H-4,7-ethanoinden-6-yl)oxy]ethyl acrylate, tricyclo[5,2,1,0^{2,6}]decyl acrylate, and tetracyclo[4,4,0,1^{2.5},1^{7.10}]dodecanyl acrylate. Without wishing to be bound by theory, it is believed that including at least one mono (meth)acrylate containing compound can enhance the mechanical properties of the film formed by the dielectric film-forming composition described herein (e.g., by forming a polymer and/or reacting (or crosslinking) with the reactive functional compound).

In some embodiments, the dielectric film-forming composition optionally includes one or more (e.g., two, three, or four) inorganic filler. In some embodiments, the inorganic filler is selected from the group consisting of silica, alumina, titania, zirconia, hafnium oxide, CdSe, CdS, CdTe, CuO, zinc oxide, lanthanum oxide, niobium oxide, tungsten oxide, strontium oxide, calcium titanium oxide, sodium titanate, barium sulfate, barium titanate, barium zirconate, and potassium niobate. Preferably, the inorganic fillers are in a granular form having an average size of about 0.05-2.0 microns. In some embodiments, the filler is an inorganic particle containing a ferromagnetic material. Suitable ferromagnetic materials include elemental metals (such as iron, nickel, and cobalt) or their oxides, sulfides and oxyhydroxides, and intermetallics compounds such as Awaruite (Ni₃Fe), Wairaruite (CoFe), Co₁₇Sm₂, and Nd₂Fe₁₄B.

In some embodiments, the amount of the inorganic filler (e.g., silica filler) is at least about 1 weight % (e.g., at least about 2 weight %, at least about 5 weight %, at least about 8 weight %, or at least about 10 weight %) and/or at most about 30 weight % (e.g., at most about 25 weight %, at most about 20 weight %, or at most about 15 weight %) of the total weight of the dielectric film-forming composition.

In some embodiments, the dielectric film-forming composition of this disclosure optionally further includes one or more (e.g., two, three, or four) adhesion promoter. Suitable adhesion promoters are described in “Silane Coupling Agent” Edwin P. Plueddemann, 1982 Plenum Press, New York, the contents of which are hereby incorporated by reference.

In some embodiments, the amount of the optional adhesion promoter is at least about 0.5 weight % (e.g., at least about 0.8 weight %, at least about 1 weight %, or at least about 1.5 weight %) and/or at most about 4 weight % (e.g., at most about 3.5 weight %, at most about 3 weight %, at most about 2.5 weight %, or at most about 2 weight %) of the total weight of the dielectric film-forming composition.

The dielectric film-forming composition of this disclosure can also optionally contain one or more (e.g., two, three, or four) surfactant (e.g., ionic or non-ionic surfactants). A commercially available surfactant is PolyFox 6320 available from OMNOVA Solutions. Other examples of suitable surfactants include, but are not limited to, the surfactants described in JP-A-62-36663, JP-A-61-226746, JP-A-61-226745, JP-A-62-170950, JP-A-63-34540, JP-A-7-230165, JP-A-8-62834, JP-A-9-54432 and JP-A-9-5988, the contents of which are hereby incorporated by reference.

In some embodiments, the amount of the surfactant is at least about 0.005 weight % (e.g., at least about 0.01 weight % or at least about 0.1 weight %) and/or at most about 1 weight % (e.g., at most about 0.5 weight % or at most about 0.2 weight %) of the total weight of the dielectric film-forming composition.

The dielectric film-forming composition of the present disclosure can optionally contain one or more (e.g., two, three, or four) copper passivation reagent. Examples of suitable copper passivation reagents include triazole compounds, imidazole compounds and tetrazole compounds, Triazole compounds can include triazoles, benzotriazoles, substituted triazoles, and substituted benzotriazoles. Examples of triazole compounds include, but are not limited to, 1,2,4-triazole; 1,2,3-triazole, or triazoles substituted with substituents such as C₁-C₈ alkyl (e.g., 5-methyltriazole), amino, third, mercapto, imino, carboxy and nitro groups. Specific examples include benzotriazole, tolyltriazole, 5-methyl-1,2,4-triazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, 2-[3-2H-benzotriazol-2-yl)-4-hydroxyphenyl] ethyl methacrylate (BTZ-AC) halo-benzotriazoles (halo=F, Cl, Br or I), naphthotriazole, and the like. Examples of imidazole include, but are not limited to, 2-alkyl-4-methyl imidazole, 2-phenyl-4-alkyl imidazole, 2-methyl-4(5)-nitroimidazole, 5-methyl-4-nitroimidazole, 4-Imidazolemethanol hydrochloride, and 2-mercapto-1-methylimidazole. Examples of tetrazole include 1-H-tetrazole, 5-methyl-1H-tetrazole, 5-phenyl-1H-tetrazole, 5-amino-1H-tetrazole,1-phenyl-5-mercapto-1H-tetrazole, 5,5′-bis-1H-tetrazole,1-methyl-5-ethyltetrazole, 1-methyl-5-mercaptotetrazole, 1-carboxymethyl-5-mercaptotetrazole, and the like. The amount of the optional copper passivation agent; if employed, is at least about 0.1 weight % (e.g., at least about 0.2 weight % or at least about 0.5 weight %) and/or at most about 3.0 weight % (e.g., at most about 2.0 weight % or at most about 1.0 weight %) of the entire weight of the dielectric film-forming composition of this disclosure.

In some embodiments, the photosensitive dielectric film-forming composition of this disclosure can optionally contain one or more (e.g., two, three, or four) plasticizers, antioxidants, dyes, and/or colorants.

In some embodiments, a dielectric film can be prepared from a dielectric film-forming composition of this disclosure by a process containing the steps of: (a) coating the dielectric film-forming composition described herein on a substrate (e.g. a semiconductor substrate) to form a dielectric film; and (b) optionally baking the film at an elevated temperature (e.g., from about 50° C. to about 150° C.) for a period of time (e.g., from about 20 seconds to about 600 seconds).

Coating methods for preparation of the dielectric film include, but are not limited to, (1) spin coating, (2) spray coating; (3) roll coating, (4) rod coating, (5) rotation coating, (6) slit coating, (7) compression coating, (8) curtain coating, (9) die coating, (10) wire bar coating; (11) knife coating and (12) lamination of dry film. In case of coating methods (1)-(11), the dielectric film-forming composition is typically provided in the form of a solution. One skilled in the art would choose the appropriate solvent type and solvent concentration based on the coating type.

Substrates can have circular, square or rectangular shapes such as wafers or panels in various dimensions. Examples of suitable substrates are epoxy molded compound (EMC), silicon, glass, copper, stainless steel, copper cladded laminate (CCL), aluminum, silicon oxide and silicon nitride. Substrates can be flexible such as polyimide, PEEK, polycarbonate, and polyester films. Substrates can have surface mounted or embedded chips, dyes, or packages. Substrates can be sputtered or pre-coated with a combination of seed layer and passivation layer. In some embodiments, the substrates mentioned herein can be a semiconductor substrate. As used herein, a semiconductor substrate is a substrate (e.g., a silicon or copper substrate or wafer) that becomes a part of a final electronic device.

The thickness of the dielectric film of this disclosure is not particularly limited. In some embodiments, the dielectric film has a film thickness of at least about 1 micron (e.g., at least about 2 microns, at least about 3 microns, at least about 4 microns, at least about 5 microns, at least about 6 microns, at least about 8 microns, at least about 10 microns, at least about 15 microns, at least about 20 microns, or at least about 25 microns) and/or at most about 100 microns (e.g., at most about 90 microns, at most about 80 microns, at most about 70 microns at most about 60 microns, at most about 50 microns, at most about 40 microns, or at most about 30 microns). In some embodiments; the thickness of the dielectric film is less than about 5 microns (e.g., less than about 4.5 microns, less than about 4.0 microns, less than about 3.5 microns, less than about 3.0 microns, less than about 2.5 microns, or less than about 2.0 microns).

In some embodiments, when the dielectric composition is photosensitive; the process to prepare a patterned photosensitive dielectric film includes converting the photosensitive dielectric film into a patterned dielectric film by a lithographic process. In such cases, the conversion can include exposing the photosensitive dielectric film to high energy radiation (such as electron beams, ultraviolet light, and X-ray) using a patterned mask.

After the exposure, the dielectric film can be heat treated to at least about 50° C. (e.g., at least about 55° C., at least about 60° C., or at least about 65° C.) to at most about 100° C. (e.g., at most about 95° C., or at most about 90° C., at most about 85° C., at most about 80° C., at most about 75° C., or at most about 70° C.) for at least about 60 seconds (e.g., at least about 65 seconds, or at least about 70 seconds) to at most about 240 seconds (e.g., at most about 180 seconds, at most about 120 seconds or at most about 90 seconds). The heat treatment is usually accomplished by use of a hot plate or oven.

After the exposure and heat treatment, the dielectric film can be developed to remove unexposed portions by using a developer to form openings or a relief image on the substrate. Development can be carried out by, for example, an immersion method or a spraying method. Microholes and fine lines can be generated in the dielectric film on the laminated substrate after development.

In some embodiments, the dielectric film can be developed by use of an organic developer. Examples of such developers can include, but are not limited to, gamma-butyrolactone (GBL), dimethyl sulfoxide (DMSO), N,N-diethylacetamide, methyl ethyl ketone (MEK), methyl isobutyl ketone (MIBK), 2-heptanone, cyclopentanone (CP), cyclohexanone, n-butyl acetate (nBA), propylene glycol methyl ether acetate (PGMEA), propylene glycol methyl ether (PGME), ethyl lactate (EL), propyl lactate, 3-methyl-3-methoxybutanol, tetralin, isophorone, ethylene glycol monobutyl ether, diethylene glycol monoethyl ether, diethylene glycol monoethyl ether acetate, diethylene glycol dimethyl ether, diethylene glycol methylethyl ether, triethylene glycol monoethyl ether, dipropylene glycol monomethyl ether, methyl 3-methoxypropionate, ethyl 3-ethoxypropionate, diethyl malonate, ethylene glycol, 1,4:3,6-dianhydrosorbitol, isosorbide dimethyl ether, 1,4:3,6-dianhydrosorbitol 2,5-diethyl ether (2,5-diethylisosorbide) and mixtures thereof. Preferred developers are gamma-butyrolactone (GBL), cyclopentanone (CP), cyclohexanone, ethyl lactate (EL), n-butyl acetate (nBA) and dimethylsulfoxide (DMSO). More preferred developers are gamma-butyrolactone (GBL), cyclopentanone (CP) and cyclohexanone. These developers can be used individually or in combination of two or more to optimize the image quality for the particular composition and lithographic process.

In some embodiments, the dielectric film can be developed by using an aqueous developer. When the developer is an aqueous solution, it preferably contains one or more aqueous bases. Examples of suitable bases include, but are not limited to, inorganic alkalis (e.g., potassium hydroxide, sodium hydroxide), primary amines (e.g., ethylamine, n-propylamine), secondary amines (e.g. diethylamine, di-n-propylamine), tertiary amines (e.g., triethylamine), alcoholamines (e.g., triethanolamine), quaternary ammonium hydroxides (e.g., tetramethylammonium hydroxide or tetraethylammonium hydroxide), and mixtures thereof. The concentration of the base employed will vary depending on, e.g., the base solubility of the polymer employed. The most preferred aqueous developers are those containing tetramethylammonium hydroxide (TMAH). Suitable concentrations of TMAH range from about 1% to about 5%.

In some embodiments, after the development by an organic developer, an optional rinse treatment can be carried out with an organic rinse solvent to remove residues. Suitable examples of organic rinse solvents include, but are not limited to, alcohols such as isopropyl alcohol, methyl isobutyl carbinol (MIBC), propylene glycol monomethyl ether (PGME), and amyl alcohol; esters such as n-butyl acetate (nBA), ethyl lactate (EL) and propylene glycol monomethyl ether acetate (PGMEA); ketnoes such as methyl ethyl ketone, and mixtures thereof.

In some embodiments, after the development step or the optional rinse treatment step, an optional baking step (e.g., post development bake) can be carried out at a temperature ranging from at least about 120° C. (e.g., at least about 130° C., at least about 140° C., at least about 150° C., at least about 160° C., at least about 170° C., or at least about 180° C.) to at most about 250° C. (e.g., at most about 240° C., at most about 230° C., at most about 220° C., at most about 210° C., at most about 200° C. or at most about 190° C.). The baking time is at least about 5 minutes (e.g., at least about 10 minutes, at least about 20 minutes, at least about 30 minutes, at least about 40 minutes, at least about 50 minutes, or at least about 60 minutes) and/or at most about 5 hours (e.g., at most about 4 hours, at most about 3 hours, at most about 2 hours, or at most about 1.5 hours). This baking step can remove residual solvent from the remaining dielectric film and can further crosslink the remaining dielectric film. Post development bake can be done in air or preferably, under a blanket of nitrogen and may be carried out by any suitable heating means.

In some embodiments, the patterned dielectric film includes at least one element having a feature size of at most about 10 microns (e.g., at most about 9 microns, at most about 8 microns, at most about 7 microns, at most about 6 microns, at most about 5 microns, at most about 4 microns, at most about 3 microns, at most about 2 microns, or at most about 1 microns). One important aspect of this disclosure is that the dielectric films prepared from the dielectric film-forming composition described herein are capable of producing a patterned film with a feature size of at most about 3 microns (e.g., at most 2 microns or at most 1 micron) by a laser ablation process.

In some embodiments, the aspect ratio (ratio of height to width) of a feature (e.g., the smallest feature) of the patterned dielectric film of this disclosure is at least about 1/3 (e.g., at least about 1/2, at least about 1/1, at least about 2/1, at least about 3/1, at least about 4/1, or at least about 5/1).

In some embodiments (e.g., when the dielectric film-forming composition is non-photosensitive), the process to prepare patterned dielectric film include converting the dielectric film into patterned dielectric film by a laser ablation technique. Direct laser ablation process with an excimer laser beam is generally a dry, one step material removal to form openings (or patterns) in the dielectric film. In some embodiments, the wavelength of the laser is 351 nm or less (e.g., 351 nm, 308 nm, 248 nm or 93 nm). Examples of suitable laser ablation processes include, but are not limited to, the processes described in U.S. Pat. Nos. 7,598,167, 6,667,551, and 6,114,240, the contents of which are hereby incorporated by reference.

In embodiments when the dielectric film-forming composition is non-photosensitive, the composition can be used to form the bottom layer in a bilayer photoresist. In such embodiment, the top layer of the bilayer photoresist can be a photosensitive layer and can be patterned upon exposure to high energy radiation. The pattern in the top layer can be transferred to the bottom dielectric layer (e.g., by etching). The top layer can then be removed (e.g., by using a wet chemical etching method) to form a patterned dielectric film.

In some embodiments, this disclosure features a process for depositing a metal layer (e.g., to create an embedded copper trace structure) that includes the steps of: (a) forming a patterned dielectric film having openings; and d) depositing a metal layer (e.g., an electrically conductive metal layer) in at least one opening in the patterned dielectric film. For example, the process can include the steps of: (a) depositing a dielectric film-forming composition of this disclosure on a substrate (e.g., a semiconductor substrate) to form a dielectric film; (b) exposing the dielectric film to a source of radiation or heat or a combination thereof (e.g., through a mask); (c) patterning the dielectric film to form a patterned dielectric film having openings; and (d) depositing a metal layer (e.g., an electrically conductive metal layer) in at least one opening in the patterned dielectric film. In some embodiments, steps (a)-(d) can be repeated one or more (e.g., two, three, or four) times.

In some embodiments, this disclosure features a process to deposit a metal layer (e.g., an electrically conductive copper layer to create an embedded copper trace structure) on a semiconductor substrate. In some embodiment; to achieve this, a seed layer conformal to the patterned dielectric film is first deposited on the patterned dielectric film (e.g., outside the openings in the film). Seed layer can contain a barrier layer and a metal seeding layer (e.g., a copper seeding layer). In some embodiments, the barrier layer is prepared by using materials capable of preventing diffusion of an electrically conductive metal (e.g., copper) through the dielectric layer. Suitable materials that can be used for the barrier layer include, but are not limited to, tantalum (Ta), titanium (Ti), tantalum nitride (TiN), tungsten nitride (WN), and Ta/TaN. A suitable method of forming the barrier layer is sputtering (e.g., PVD or physical vapor deposition). Sputtering deposition has some advantages as a metal deposition technique because it can be used to deposit many conductive materials, at high deposition rates, with good uniformity and low cost of ownership. Conventional sputtering fill produces relatively poor results for deeper, narrower (high-aspect-ratio) features. The fill factor by sputtering deposition has been improved by collimating the sputtered flux, Typically, this is achieved by inserting between the target and substrate a collimator plate having an array of hexagonal cells.

Next step in the process is metal seeding deposition. A thin metal (e.g., an electrically conductive metal such as copper) seeding layer can be formed on top of the barrier layer in order to improve the deposition of the metal layer (e.g., a copper layer) formed in the succeeding step.

Next step in the process is depositing an electrically conductive metal layer (e.g., a copper layer) on top of the metal seeding layer in the openings of the patterned dielectric film wherein the metal layer is sufficiently thick to fill the openings in the patterned dielectric film. The metal layer to fill the openings in the patterned dielectric film can be deposited by plating (such as electroless or electrolytic plating), sputtering, plasma vapor deposition (PVD), and chemical vapor deposition (CVD). Electrochemical deposition is generally a preferred method to apply copper since it is more economical than other deposition methods and can flawlessly fill copper into the interconnect features. Copper deposition methods generally should meet the stringent requirements of the semiconductor industry. For example, copper deposits should be uniform and capable of flawlessly filling the small interconnect features of the device, for example, with openings of 100 nm or smaller. This technique has been described, e.g., in U.S. Pat. No. 5,891,804 (Havemann et al.), U.S. Pat. No. 6,399,486 (Tsai et al.), and U.S. Pat. No. 7,303,992 (Paneccasio et al.), the contents of which are hereby incorporated by reference.

In some embodiments, the process of depositing an electrically conductive metal layer further includes removing overburden of the electrically conductive metal or removing the seed layer (e.g., the barrier layer and the metal seeding layer), In some embodiments, the overburden of the electrically conductive metal layer (e.g., a copper layer) is at most about 3 microns (e.g., at most about 2.8 microns, at most about 2.6 microns, at most about 2.4 microns, at most about 2.2 microns, at most about 2.0 microns, or at most about 1.8 microns) and at least about 0.4 micron (e.g., at least about 0.6 micron, at least about 0.8 micron, at least about 1.0 micron, at least about 1.2 micron, at least about 1.4 micron or at least about 1.6 microns). Examples of copper etchants for removing copper overburden include an aqueous solution containing cupric chloride and hydrochloric acid or an aqueous mixture of ferric nitrate and hydrochloric acid. Examples of other suitable copper etchants include, but are not limited to, the copper etchants described in U.S. Pat. Nos. 4,784,785, 3,361,674, 3,816,306, 5,524,780, 5,650,249, 5,431,776, and 5,248,398, and US Application Publication No. 2017175274, the contents of which are hereby incorporated by reference.

Some embodiments describe a process for surrounding a metal structured substrate containing conducting metal (e.g., copper) wire structures forming a network of lines and interconnects with the dielectric film of this disclosure. The process can include the steps of:

a) providing a substrate containing conducting metal wire structures that form a network of lines and interconnects on the substrate;

b) depositing a dielectric film-forming composition of this disclosure on the substrate to form a dielectric film (e.g., that surrounds the conducting metal lines and interconnects; and

c) exposing the dielectric film to a source of radiation or heat or a combination of radiation and heat (with or without a mask).

The above steps can be repeated multiple times (e.g., two, three, or four times) to form a complex multi-layered three-dimensional object.

In some embodiments, this disclosure features a method of preparing a dry film structure. The method can include:

a) coating a carrier substrate (e.g., a substrate including at least one polymeric or plastic film) with a dielectric film-forming composition described herein;

b) drying the coated dielectric film-forming composition to form a dry film; and

c) optionally, applying a protective layer to the dry film.

In some embodiments, the carrier substrate is a single or multiple layer polymeric or plastic film, which can include one or more polymers (e.g., polyethylene terephthalate). In some embodiments, the carrier substrate has excellent optical transparency and it is substantially transparent to actinic irradiation used to form a relief pattern in the polymer layer. The thickness of the carrier substrate is preferably in the range of at least about 10 μm (e.g., at least about 15 μm, at least about 20 μm, at least about 30 μm, at least about 40 μm, at least about 50 μm or at least about 60 μm) to at most about 150 μm (e.g., at most about 140 μm, at most about 120 μm, at most about 100 μm, at most about 90 μm, at most about 80 μm, or at most about 70 μm).

In some embodiments, the protective layer is a single or multiple layer film, which can include one or more polymers (e.g., polyethylene or polypropylene). Examples of carrier substrates and protective layers have been described in, e.g., U.S. Application Publication No. 2016/0313642, the contents or which are hereby incorporated by reference.

In some embodiments, the dielectric film of the dry film can be delaminated from carrier layer as a self-standing dielectric film. A self-standing dielectric film is a film that can maintain its physical integrity without using any support layer such as a carrier layer. In some embodiments, the self-standing dielectric film is not crosslinked or cured and can include the components of the dielectric film-forming composition described above except for the solvent.

In some embodiments, the dielectric loss tangent or dissipation factor of the film prepared from dielectric film-forming composition of this disclosure measured at 10 GHz, 15 GHz, and/or 35 GHz is in the range of from at least about 0.001 (e.g., at least about 0.002, at least about 0.003, at least about 0.004, at least about 0.005, at least about 0.01, or at least about 0.05) to at most about 0.1 (e.g., at most about 0.08, at most about 0.06, at most about 0.05, at most about 0.04, at most about 0.02, at most about 0.01, at most about 0,008, at most about 0.006, or at most about 0.005).

In some embodiments, the dielectric film of the dry film structure can be laminated to a substrate (e.g., a semiconductor substrate such as a wafer) using a vacuum laminator at about 50° C. to about 140° C. after pre-laminating of the dielectric film of the dry film structure with a plane compression method or a hot roll compression method. When the hot roll lamination is employed, the dry film structure can be placed into a hot roll laminator, the optional protective layer can be peeled away from the dielectric film/carrier substrate, and the dielectric film can be brought into contact with and laminated to a substrate using rollers with heat and pressure to form an article containing the substrate, the dielectric film, and the carrier substrate. The dielectric film can then be exposed to a source of radiation or heat (e.g., through the carrier substrate) to form a crosslinked photosensitive dielectric film. In some embodiments, the carrier substrate can be removed before exposing the dielectric film to a source of radiation or heat.

Some embodiments of this disclosure describe a process of generating a planarizing dielectric film on a substrate with copper pattern. In some embodiments, the process includes depositing a dielectric film-forming composition onto a substrate with copper pattern to form a dielectric film. In some embodiments, the process includes steps of:
a. providing a dielectric film-forming composition of this disclosure,
b. depositing the dielectric film-forming composition onto a substrate with copper pattern to form a dielectric film, wherein the difference in the highest and lowest points on a top surface of the dielectric film is less than about 2 microns (e.g., less than 1.5 microns, less than 1 micron or less than 0.5 micron).

In some embodiments, this disclosure features an article containing at least one patterned dielectric film formed by a process described herein. Examples of such articles include a semiconductor substrate, a flexible film for electronics, a wire isolation, a wire coating, a wire enamel, or an inked substrate. In some embodiments, this disclosure features semiconductor devices that include one or more of these articles. Examples of semiconductor devices that can be made from such articles include an integrated circuit, a light emitting diode, a solar cell, and a transistor.

The contents of all publications cited herein (e.g., patents, patent application publications, and articles) are hereby incorporated by reference in their entirety.

The present disclosure is illustrated in more detail with reference to the following examples, which are for illustrative purposes and should not be construed as limiting the scope of the present disclosure.

### EXAMPLES

### Composition Example 1 (CE-1)

A photosensitive dielectric film-forming composition (CE-1) was prepared by using 100 parts of a 29.19% solution of a polyimide polymer (P-1) shown below having a weight average molecular weight of 54,000 Daltons in cyclopentanone, 2.76 parts of cyclopentanone, 41.5 parts of propylene carbonate, 1.75 parts of a 0.5 wt % solution of PolyFox 6320 (a surfactant available from OMNOVA Solutions) in propylene carbonate, 1.46 parts of methacryloxypropyltrimethoxy silane (an adhesion promoter), 0.88 parts of 2-(O-benzoyloxime)-1-[4-(phenylthio)phenyl]-1,2-octanedione (Irgacure OXE-1 available from BASF, a photoinitiator), 0.06 parts of monomethyl ether hydroquinone (an antioxidant), 10.95 parts of tetraethylene glycol diacrylate (a reactive functional compound), 3.65 parts of pentaerythritol triacrylate (a reactive functional compound), 2.92 parts of 2,2-bis(4-cyanatophenyl)propane (a cyanate ester) and 0.15 parts of 5-methyl benzotriazole (a copper corrosion inhibitor). After being stirred mechanically for 24 hours, the solution was filtered by using a 0.2 micron filter (Ultradyne from Meissner Corporation, cat #CLTM0.2-552).

The Tg of a dielectric film formed by this composition was 267° C., which is higher than the Tg of a dielectric film formed by Comparative Composition 1 described below (248° C.).

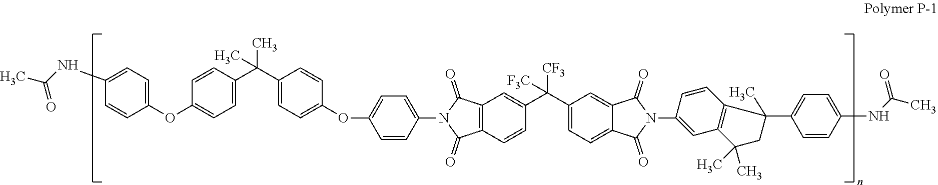

### Lithographic Process Example 1

The photosensitive composition CE-1 was spin coated on a silicon wafer and baked at 95° C. for 6 minutes using a hot plate to form a coating with a thickness of 7.95 microns. The photosensitive polyimide film was exposed at various levels of exposure energy using a Cannon 4000 IE i-line stepper.

Unexposed portions were removed by using cyclopentanone as a developer (1×40 seconds of dynamic development), followed by rinsing the developed film with PGMEA for 15 seconds to form a pattern. A resolution of 4 microns at a photospeed of 100 mJ/cm² was achieved. The film thickness loss was 17.9%.

### Composition Example 2 (CE-2)

A photosensitive dielectric film-forming composition CE-2 was prepared by using 100 parts of a 29.19% solution of a polyimide polymer (P-1) having a weight average molecular weight of 54,000 Daltons in cyclopentanone, 2.76 parts of cyclopentanone, 41.5 parts of propylene carbonate, 1.75 parts of a 0.5 wt % solution of PolyFox 6320 in propylene carbonate, 1.46 parts of methacryloxypropyltrimethoxy silane, 0.88 parts of Irgacure OXE-1, 0.06 parts of monomethyl ether hydroquinone, 10.95 parts of tetraethylene glycol diacrylate, 3.65 parts of pentaerythritol triacrylate, 5.84 parts of 2,2-bis(4-cyanatophenyl)propane and 0.15 parts of 5-methyl benzotriazole. After being stirred mechanically for 24 hours, the solution was filtered by using a 0.2 micron filter (Ultradyne from Meissner Corporation, cat #CLTM0.2-552).

The Tg of a dielectric film formed by this composition was 273° C., which is higher than the Tg of a dielectric film formed by Comparative Composition 1 described below (248° C.).

### Composition Example 3 (CE-3)

A photosensitive dielectric film-forming composition (CE-3) was prepared by using 100 parts of a 29.19% solution of a polyimide polymer (P-1) having a weight average molecular weight of 54,000 Daltons in cyclopentanone, 2.76 parts of cyclopentanone, 41.5 parts of propylene carbonate, 1.75 parts of a 0.5 wt % solution of PolyFox 6320 in propylene carbonate, 1.46 parts of methacryloxypropyltrimethoxy silane, 0.88 parts of Irgacure OXE-1, 0.06 parts of monomethyl ether hydroquinone, 10.95 parts of tetraethylene glycol diacrylate, 3.65 parts of pentaerythritol triacrylate, 4.3 parts of 2,2-bis(4-cyanatophenyl)propane and 0.15 parts of 5-methyl benzotriazole. After being stirred mechanically for 24 hours, the solution was filtered by using a 0.2 micron filter (Ultradyne from Meissner Corporation, cat #CLTM0.2-552).

The Tg of a dielectric film formed by this composition was 270° C., which is higher than the Tg of a dielectric film formed by Comparative Composition 1 described below (248° C.).

### Composition Example 4 (CE-4)

A photosensitive dielectric film-forming composition (CE-4) was prepared by using 100 parts of a 29.19% solution of a polyimide polymer (P-1) having a weight average molecular weight of 54,000 Daltons in cyclopentanone, 2.76 parts of cyclopentanone, 41.5 parts of propylene carbonate, 1.75 parts of a 0.5 wt % solution of PolyFox 6320 in propylene carbonate, 1.17 parts of methacryloxypropyltrimethoxy silane, 0.29 parts of gamma glycidoxypropyltrimethoxy silane (Silquest A-187), 0.88 parts of Irgacure OXE-1, 0.06 parts of monomethyl Ether hydroquinone, 10.95 parts of tetraethylene glycol diacrylate, 3.65 parts of pentaerythritol triacrylate, 2.92 parts of 2,2-bis(4-cyanatophenyl)propane and 0.15 parts of 5-methyl benzotriazole. After being stirred mechanically for 24 hours, the solution was filtered by using a 0.2 micron filter (Ultradyne from Meissner Corporation, cat #CLTM0.2-552).

### Composition Example 5 (CE-5)

A photosensitive dielectric film-forming composition (CE-5) was prepared by using 100 parts of a 29.19% solution of a polyimide polymer (P-1) having a weight average molecular weight of 54,000 Daltons in cyclopentanone, 2.76 parts of cyclopentanone, 41.5 parts of propylene carbonate, 1.75 parts of a 0.5 wt % solution of PolyFox 6320 in propylene carbonate, 1.46 parts of gamma glycidoxypropyltrimethoxy silane, 0.88 parts of Irgacure OXE-1, 0.06 parts of monomethyl ether hydroquinone, 10.95 parts of tetraethylene glycol diacrylate, 3.65 parts of pentaerythritol triacrylate, 2.92 parts of 2,2-bis(4-cyanatophenyl)propane and 0.15 parts of 5-methyl benzotriazole, After being stirred mechanically for 24 hours, the solution was filtered by using a 0.2 micron fitter (Ultradyne from Meissner Corporation, cat #CLTM0.2-552).

### Comparative Composition Example 1 (CCE-1)

A photosensitive dielectric film-forming composition CCE-1 was prepared by using 100 parts of a 29.19% solution of a polyimide polymer (P-1) having a weight average molecular weight of 54,000 in cyclopentanone, 2.76 parts of cyclopentanone, 41.5 parts of propylene carbonate, 1.75 parts of a 0.5 wt % solution of PolyFox 6320 in propylene carbonate, 1.46 parts of methacryloxypropyltrimethoxy silane, 0.88 parts Irgacure OXE-1, 0.06 parts of monomethyl ether hydroquinone, 10.95 parts of tetraethylene glycol diacrylate, 3.65 parts of pentaerythritol triacrylate and 0.15 parts of 5-methyl benzotriazole. In other words, composition CCE-1 did not include a cyanate ester compound. After being stirred mechanically for 24 hours, the above solution was filtered by using a 0.2 micron filter (Ultradyne from Meissner Corporation, cat #CLTM0.2-552). The Tg of a dielectric film formed by this composition was 248° C.

### Composition Example 6 (CE-6)

A photosensitive dielectric film-forming composition (CE-6) was prepared by using 100 parts of a 31.21% solution of a polyimide polymer (P-2) having the structure shown below and a weight average molecular weight of 24,500 in GBL, 10.1 parts of GBL, 44.45 parts of propylene carbonate, 1.75 parts of a 0.5 wt % solution of PolyFox 6320 in propylene carbonate, 1.25 parts of methacryloxypropyltrimethoxy silane, 0.31 parts of gamma glycidoxypropyltrimethoxysilane (Silquest A-187), 0.94 parts of Irgacure OXE-1, 0.06 parts of monomethyl ether hydroquinone, 11.70 parts of tetraethylene glycol diacrylate, 3.90 parts of pentaerythritol triacrylate, 3.12 parts of 2,2-bis(4-cyanatophenyl)propane and 0.16 parts of 5-methyl benzotriazole. After being stirred mechanically for 24 hours, the solution was filtered by using a 0.2 micron filter (Ultradyne from Meissner Corporation; cat #CLTM0.2-552).

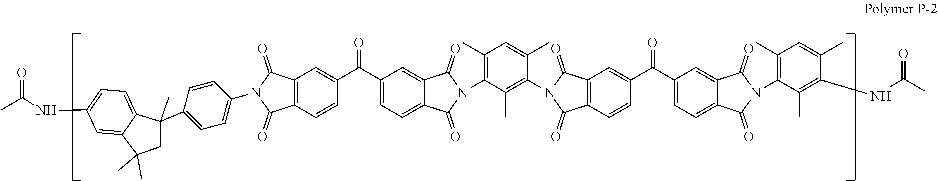

### Composition Example 7 (CE-7)

A photosensitive dielectric film-forming composition CE-7 is prepared by using 100 parts of a 29.19% solution of a polyimide polymer (P-1) having weight average molecular weight of 54,000 Daltons in cyclopentanone, 2.76 parts of cyclopentanone, 41.5 parts of propylene carbonate, 1.75 parts of a 0.5 wt % solution of PolyFox 6320 in propylene carbonate, 1.46 parts of triethoxy silylpropyl ethylcarbamate, 0.88 parts of 1-[9-ethyl-6-(2-methylbenzoyl)-9H-carbazol-3-yl]ethanone 1-(O-acetyloxime) (Irgacure OXE-2 from BASF), 0.06 parts of monomethyl ether hydroquinone, 10.95 parts of 1,6-hexanediol dimethacrylate, 3.65 parts of 1,3-butanediol tri(meth)acrylate, 2.92 parts of DCP Novolak (Product Primaset® DT-4000) (a cyanate ester compound) and 0.15 parts of 5-methyl benzotriazole. After being stirred mechanically for 24 hours, the solution is filtered by using a 0.2 micron filter (Ultradyne from Meissner Corporation, cat #CLTM0.2-552).

### Composition Example 8 (CE-8)

A photosensitive dielectric film-forming composition (CE-8) is prepared by using 30 parts of a polybenzoxazole precursor polymer described in Synthetic Example 3 (polymer P-3) of U.S. Pat. No. 6,929,891, 2.76 parts of cyclopentanone, 41.5 parts of propylene carbonate, 1.75 parts of a 0.5 wt % solution of PolyFox 6320 (available from OMNOVA Solutions) in propylene carbonate, 1.46 parts of 3-(triethoxysilyl)propylsuccinic anhydride, 0.88 parts of 1,8-bis[9-(2-ethylhexyl)-6-nitro-9H-carbazol-3-yl]-1,8-bis(O-acetyloxime), 0.06 parts of monomethyl ether hydroquinone, 10.95 parts of tetraethyleneglycol dimethacrylate, 3.65 parts of 1,4-butanediol triacrylate, 1.46 parts of 2,2-bis(4-cyanatophenyl)propane and 1.46 parts of DCP Novolak (Product Primaset® UT-4000) and 0.15 parts of 5-methyl benzotriazole. After being stirred mechanically for 24 hours, the solution is filtered by using a 0.2 micron filter (Ultradyne from Meissner Corporation, cat #CLTM0.2-552).

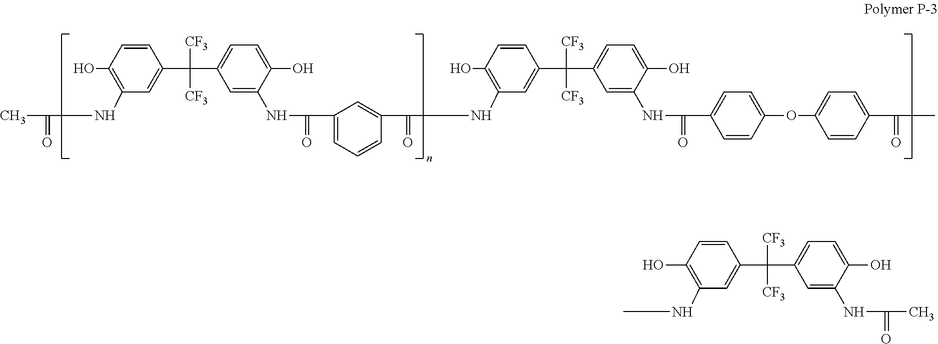

### Composition Example 9 (CE-9)

A photosensitive dielectric film-forming composition (CE-9) is prepared by using 30 parts of a 29.19% solution of a polyamic acid ester produced from 4,4′-oxidiphthalic anhydride (ODPA), 4,4′-diaminophenyl ether (ODA) (polymer P-4), and 2-hydroxyethyl methacrylate, 2.76 parts of cyclopentanone, 41.5 parts of propylene carbonate, 1.75 parts of a 0.5 wt % solution of PolyFox 6320 in propylene carbonate, 1.17 parts of 3-(triethoxysilyl)propylsuccinic anhydride, 0.29 parts of gamma glycidoxypropyltrimethoxysilane (Silquest A-187); 0.88 parts of 1-hydroxycyclohexyl phenyl ketone (Irgacure 184 from BASF), 0.06 parts of monomethyl ether hydroquinone, 10.95 parts of 1,12-dodecanediol dimethacrylate, 3.65 parts of dipentaerythritol hexaacrylate, 2.92 parts of Novolak (Product Primaset® PT-30) (a cyanate ester compound) and 0.15 parts of 5-methyl benzotriazole, After being stirred mechanically for 24 hours, the solution is filtered by using a 0.2 micron filter (Ultradyne from Meissner Corporation, cat #CLTM0.2-552).

### Composition Example 10 (CE-10)

A photosensitive dielectric film-forming composition (CE-10) is prepared by using 100 parts of a 29.19% a solution of a polyimide polymer (P-1) having a weight average molecular weight of 54,000 in cyclopentanone, 2.76 parts of cyclopentanone, 41.5 parts of propylene carbonate, 1.75 parts of a 0.5 wt % solution of PolyFox 6320 in propylene carbonate, 1.17 parts of 2-cyanoethyltriethoxysilane, 0.29 parts of gamma glycidoxypropyltrimethoxysilane (Silquest A-187), 0.88 parts of NCI-831 (ADEKA Corp.), 0.06 parts of monomethyl ether hydroquinone, 10.95 parts of 1,3-butylene glycol dimethacrylate, 3.65 parts of dipentaerythritol pentamethacrylate, 2.92 parts of BP-M (available from Hunstman as AroCy®XU 366) (a cyanate ester compound) and 0.15 parts of 5-methyl benzotriazole. After being stirred mechanically for 24 hours, the solution is filtered by using a 0.2 micron filter (Ultradyne from Meissner Corporation, cat #CLTM0.2-552).

### Composition Example 11 (CE-11)

A photosensitive dielectric film-forming composition (CE-11) is prepared by using 100 parts of a 29.19% solution of a polyimide polymer (P-1) having a weight average molecular weight of 54,000 in cyclopentanone, 2.76 parts of cyclopentanone, 41.5 parts of ethylene carbonate, 1.75 parts of a 0.5 wt % solution of PolyFox 6320 in ethylene carbonate, 1.17 parts of (N,N-diethylaminopropyl)trimethoxysilane, 0.29 parts of gamma glycidoxypropyltrimethoxysilane (Silquest A-187), 0.88 parts of NCI-930 (ADEKA Corp.), 0.06 parts of monomethyl ether hydroquinone, 10.95 parts of polyethylene glycol dimethacrylate, 3.65 parts of propoxylated (3) glycerol tri(meth)acrylate, 2.92 parts of DCP Novolak (Product Primaset®DT-4000), 2.92 parts of silica (12.0 g, Silica nanoparticles SUPSIL™ PREMIUM, monodisperse, charge-stabilized supplied by Superior Silica) and 0.15 parts of 1H tetrazole. After being stirred mechanically for 24 hours, the solution is filtered by using a 0.2 micron filter (Ultradyne from Meissner Corporation, cat #CLTM0.2-552).

### Composition Example 12 (CE-12)

A photosensitive dielectric film-forming composition CE-12 is prepared by using 100 parts of a 29.19% solution of a polyimide polymer (P-1) having a weight average molecular weight of 54,000 in cyclopentanone, 2.76 parts of cyclopentanone, 41.5 parts of butylene carbonate,1.75 parts of a 0.5 wt % solution of PolyFox 6320 in butylene carbonate, 1.17 parts of 3-trimethoxysilylpropyl thiol, 0.29 parts of gamma glycidoxypropyltrimethoxysilane (Silquest A-187), 0.88 parts of Irgacure OXE-1, 0.06 parts of monomethyl ether hydroquinone, 10.95 parts of cyclohexane dimethanol diacrylate, 3.65 parts of ditrimethylolpropane tetramethacrylate, 2.92 parts of DCP Novolak (Product Primaset® DT-4000), 2.92 parts of silica (12.0 g, Silica nanoparticles SUPSIL™ PREMIUM, monodisperse, charge-stabilized supplied by Superior Silica), 0.15 parts of 2-[3-2H-benzotriazol-2-yl)-4-hydroxyphenyl] ethyl methacrylate (BTZ-AC), and 0.15 parts of 5-methyl benzotriazole. After being stirred mechanically for 24 hours, the solution is filtered by using a 0.2 micron filter (Ultradyne from Meissner Corporation, cat #CLTM0.2-552).

### Composition Example 13 (CE-13)

A photosensitive dielectric film-forming composition CE-13 is prepared by using 100 parts of a 31.21% solution of a polyimide polymer (P-4) having the structure shown below and a weight average molecular weight of 74,500 Daltons in cyclopentanone, 10.1 parts of cyclopentanone, 44.45 parts of propylene carbonate, 1.75 parts of a 0.5 wt % solution of PolyFox 6320 in propylene carbonate, 1.25 parts of methacryloxypropyltrimethoxy silane, 0.31 parts of gamma glycidoxypropyltrimethoxysilane (Silquest A-187), 0.94 parts of Irgacure OXE-1, 0.06 parts of monomethyl ether hydroquinone, 11.70 parts of 1,4-butanediol dimethacrylate, 3.90 parts of pentaerythritol tetracrylate, 3.12 parts of 2,2-bis(4-cyanatophenyl)propane, and 0.16 parts of 5-methyl benzotriazole. After being stirred mechanically for 24 hours, the solution is filtered by using a 0.2 micron filter (Ultradyne from Meissner Corporation, cat #CLTM0.2-552)

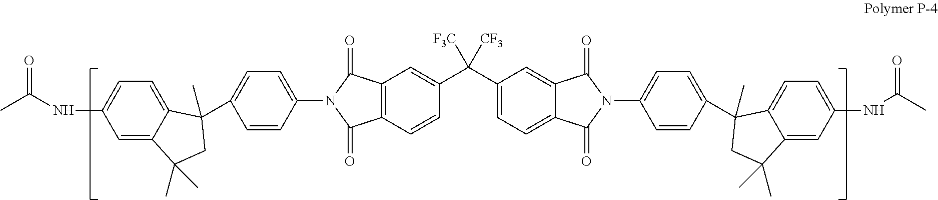

### Dry Film Example 1

A photosensitive dielectric film-forming composition was prepared by using 1345.24 g of a 31.69% solution of a polyimide polymer (P-1) having a weight average molecular weight of 58200 in cyclopentanone, 1021.91 g of propylene carbonate, 102.31 g of a 0.5 wt % solution of PolyFox 6320 in propylene carbonate, 21.31 g of methacryloxypropyltrirnethoxy silane, 34.11 g 50% solution of XU-378 (Bisphenol M Cyanate ester available from Huntsman) in cyclopentanone, 12.79 g of Irgacure OXE-1, 0.43 g of monomethyl ether hydroquinone, 138.55 g of tetraethylene glycol diacrylate, 53.39 g of pentaerythritol triacrylate, 21.32 of ethylene glycol dicyclopentenyl ether acrylate, 4.26 g of dicumyl peroxide and 0.426 g of 5-methyl benzotriazole, After being stirred mechanically for 24 hours, the solution was filtered by using a 0.2 micron filter.

This photosensitive dielectric film-forming composition was applied using a slot die coater from Fujifilm USA (Greenwood, S.C.) with a line speed of 2 feet/minutes (61 cm per minutes) with 60 microns clearance onto a polyethylene terephthalate (PET) film (TCH21, manufactured by DuPont Teijin Films USA) having a width of 16.2″ and thickness of 36 microns used as a carrier substrate and dried at 194° F. to obtain a photosensitive polymeric layer with a thickness of approximately 12.0 microns. On this polymeric layer, a biaxially oriented polypropylene film having width of 16″ and thickness of 30 microns (BOPP, manufactured by Impex Global, Houston, Tex.) was laid over by a roll compression to act as a protective layer. The carrier substrate, the photosensitive polymeric layer, and the protective layer together formed a dry film (i.e., DF-1)

### General Procedure for Mechanical Properties Measurement of Film

A filtered polymer solution was applied via spin coating onto a silicon oxide wafer to obtain a film with a thickness of approximately 21.0 microns to 23.0 microns. The coating was dried on a hot plate oven at 90° C. for 10 minutes. The film was then exposed to 500 mJ/cm². Finally, the film was baked at 170° C. for 2 hours under vacuum using YES oven. The film was delaminated from silicon oxide layer by using 2% hydrofluoric acid solution and dried in air at 50° C. for 8 hours. After cooling to room temperature, the film was characterized by DMA for Tg measurement.

Composition Examples 1-3 (CE-1 to CE-3) and Comparative Composition Example 1 (CCE-1) were used to prepare dielectric films as described above. Their Tg measurements are summarized in Table 1.

TABLE 1

| Sample No | Tg (° C.) |
|---|---|
| CCE-1 | 248 |
| CE-1 | 267 |
| CE-2 | 273 |
| CE-3 | 270 |

### Three-Dimensional Object Example 1

Photosensitive Composition Example 4 (CE-4) is spin-coated at 1200 rpm onto a silicon oxide wafer with copper-plated line/space/height pattern ranging from 8/8/6 microns to 15/15/6 microns. The coated dielectric film is baked at 95° C. for 5 minutes using a hot plate to a film thickness of about 13 microns. The photosensitive dielectric film is then blanket exposed at 500 mJ/cm² by using an LED i-line exposure tool. The dielectric film is cured at 170° C. for 2 hours in a YES oven to form a three-dimensional object where individual copper structures are surrounded by the dielectric film.

### Copper Deposition Example 1

Photosensitive Composition Example 1 (CE-1) is spin-coated at 1200 rpm onto a PVC-copper wafer. This film is then baked at 95° C. for 6 minutes using a hot plate to produce a film with a thickness of 8 μm. The photosensitive layer is exposed with a Canon i-line stepper (NA 0.45, SIGMA 0.7) through a trench test pattern reticle at a fixed dose of 500 mJ/cm² and −1 μm fixed focus. The exposed layer is then developed by using dynamic development of cyclopentanone/PGMEA as solvents for 40 seconds to resolve trenches of dimensions of 50 μm and below including ultrafine 4 μm trench patterns as observed by an optical microscope (and confirmed by cross-section scanning electron microscope (SEM). The dielectric layer thus formed is cured at 170° C. for 2 hours in a YES oven.

The wafer is then electroplated and 3.0 μm high copper lines are produced in all trenches as observed by SEM. Electrodeposition of copper is achieved using a electrolyte composition containing copper ion (30 g/L), sulfuric acid (50 g/L), chloride ion (40 ppm), polypropylene glycol) (500 ppm), disodium 3,3-dithiobis(1-propanesulfonate (200 ppm), and bis(sodium sulfopropyl) disulfide (100 pm). Electroplating is performed in a beaker while stirring using the following conditions: Anode: Copper; Plating temperature: 25° C.; Current density: 10 mA/cm²; and Time: 2 minutes. After plating, the fine trenches are cut and the copper filling conditions are inspected using optical and scanning electron microscopes to confirm that the copper is completely filled without any voids. The time of deposition is controlled to avoid overburden.

### Composition Example 14 (CE-14)

A dielectric film-forming composition CE-14 was prepared by using 100 parts of a 50% solution of BA-200 (i.e., (2,2-bis(4-cyanatophenyl)propane available from Lonza) in GBL, 17.65 parts of a 28.2% solution of a polyimide polymer (P-1) having a weight average molecular weight of 54,000 in GBL, 7.06 parts of a 0.5 wt % solution of PolyFox 6320 (available from OMNOVA Solutions) in GBL, 0.5 parts of zirconyl dimethacrylate (a cyanate curing catalyst), 0.09 parts of dicumyl peroxide, 4.71 parts of 2-hydroxy-5-acrylyloxyphenyl-2H-benzotriazoles. After being stirred mechanically for 24 hours, the solution was filtered by using a 0.2 micron filter (Ultradyne from Meissner Corporation, cat #CLTM0.2-552).

### Composition Example 15 (CE-15)

A dielectric film-forming composition CE-15 was prepared by using 100 parts of a 50% solution of XU-378 (Bisphenol M Cyanate ester available from Huntsman) in GBL, 17.65 parts of a 28.2% solution of a polyimide polymer (P-1) having a weight average molecular weight of 54,000 in GBL, 7.06 parts of a 0.5 wt % solution of PolyFox 6320 (available from OMNOVA Solutions) in GBL, 0.5 parts of zirconyl dimethacrylate, 0.09 parts of dicumyl peroxide, 4.71 parts of 2-hydroxy-5-acrylyloxyphenyl-2H-benzotriazoles. After being stirred mechanically for 24 hours, the solution was filtered by using a 0.2 micron filter (Ultradyne from Meissner Corporation, cat #CLTM0.2-552).

### Composition Example 16 (CE-16)

A dielectric film-forming composition CE-16 was prepared by using 100 parts of a 50% solution of BA-200 (i.e., 2,2-bis(4-cyanatophenyl)propane available from Lonza) in GBL, 17.65 parts of a 25% solution of a Durimide 200 polyimide polymer (available from Huntsman) in GBL, 7.06 parts of a 0.5 wt % solution of PolyFox 6320 (available from OMNOVA Solutions) in GBL, 0.5 parts of zirconyl dimethacrylate, 0.09 parts of dicumyl peroxide, 4.71 parts of 2-hydroxy-5-acrylyloxyphenyl-2H-benzotriazoles. After being stirred mechanically for 24 hours, the solution was filtered by using a 0.2 micron filter (Ultradyne from Meissner Corporation, cat #CLTM0.2-552).

### Composition Example 17 (CE-17)

A dielectric film-forming composition CE-17 was prepared by using 50 parts of a 50% solution of BA-200 (i.e., 2,2-bis(4-cyanatophenyl)propane available from Lonza) in GBL, 50 parts of a 50% solution of XU-378 (available from Huntsman) in GBL, 17.65 parts of a 31.21% solution of a polyimide polymer (P-4) having a weight average molecular weight of 74,500 Daltons in GBL, a 28.2% solution of a polyimide polymer (P 1) having a weight average molecular weight of 54,000 in GBL, 7.06 parts of a 0.5 wt % solution of PolyFox 6320 (available from OMNOVA Solutions) in GBL, 0.5 parts of zirconyl dimethacrylate, 0.09 parts of dicumyl peroxide, 4.71 parts of 2-hydroxy-5-acrylyloxyphenyl-2H-benzotriazoles. After being stirred mechanically for 24 hours, the solution was filtered by using a 0.2 micron filter (Ultradyne from Meissner Corporation, cat #CLTM0.2-552).

Table 2 summarizes the dielectric constant (K) and dissipation factor (DF) for Compositions CE-14 to CE-16.

TABLE 2

| | | |
|---|---|---|
| Sample | 15 GHz | 35 GHz |

| ID | K | DF | K | DF |
|---|---|---|---|---|
| CE-14 | 2.9 | 0.0083 | 2.94 | 0.0058 |
| CE-15 | 2.76 | 0.0047 | 2.77 | 0.0043 |
| CE-16 | 2.95 | 0.0093 | 3.09 | 0.0078 |

As shown in Table 2, CE-14 to CE-16 were able to form dielectric films with very low dielectric constant and dissipation factor.

1. A dielectric film-forming composition, comprising:
a) at least one cyanate ester compound, the at least one cyanate ester compound comprising at least two cyanate groups; and
b) at least one dielectric polymer comprising a polybenzoxazole precursor polymer, a polyimide precursor polymer, or a fully imidized polyimide polymer.

2. The composition of claim 1, wherein the at least one cyanate ester compound has Structure (I):
A-(O—C≡N)ₘ (I),
wherein m is an integer of at least 2 and A is a divalent organic group comprising a substituted or unsubstituted aromatic group.

3. The composition of claim 1, wherein the at least one cyanate ester compound has Structure (III): 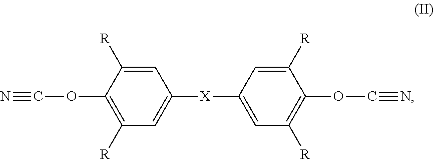
wherein R is a hydrogen atom, a C₁-C₃ alkyl group, a fully or partially halogen substituted C₁-C₃ alkyl group, or a halogen atom; and X is a single bond, —O—, —S—, —(C═O)—, —(C═O)—O—, —O—(C═O)—, —(S═O)—, —(SO₂)—, —CH₂CH₂—O—, a substituted or unsubstituted C₁-C₁₀ alkylene, a fully or partially fluoro substituted C₁-C₄ alkylene, a substituted or unsubstituted C₃-C₁₀ cycloalkylene, or one of the following groups:

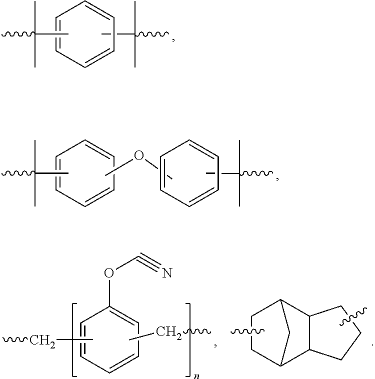

4. The composition of claim 1, wherein the at least one cyanate ester compound has Structure (III): 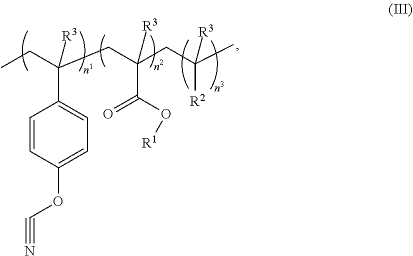
wherein n₁ is an integer of at least 2, n₂ and n₃ are independently 0 or an integer from 1 to 100, R¹ is an acid sensitive substituted alkyl, silyl, aryl, or arylalkyl group, R² is a substituted or unsubstituted C₁-C₁₀ alkyl, a substituted or unsubstituted C₃-C₁₀ cycloalkyl, a substituted or unsubstituted aryl group, or a —(C═O)—OR⁴ group, in which R⁴ is a non-acid sensitive substituted alkyl or arylalkyl group; and R³ is a substituted or unsubstituted C₁-C₁₀ alkyl, or a fluoro substituted C₁-C₄ alkyl.

5. The composition of claim 1, wherein the at least one cyanate ester compound is selected from the group consisting of 2-bis(4-cyanatophenyl)propane, hexafluorobisphenol A dicyanate, bis(4-cyanate-3,5-dimethylphenyl)methane, 1,3-bis(4-cyanatephenyl-1-(methylethylidene))benzene, bis(4-cyanatephenyl)thioether, bis(4-cyanatephenyl)ether, and a polyfunctional cyanate resin prepared from a phenol novolac, cresol novolac, or dicyclopentadiene-containing phenol resin.

6. The composition of claim 1, wherein the composition comprises at least two cyanate ester compound.

7. The composition of claim 1, wherein the at least one cyanate ester compound is in an amount of from about 2 wt % to about 55 wt % of the composition.

8. The composition of claim 1, wherein the at least one dielectric polymer is in an amount of from about 2 wt % to about 55 wt % of the composition.

9. The composition of claim 1, further comprising at least one solvent.

10. The composition of claim 9, wherein the at least one solvent s in an amount of from about 20 wt % to about 98 wt % of the composition.

11. The composition of claim 1, further comprising at least one reactive functional compound having at least two functional groups.

12. The composition of claim 11, wherein the at least one reactive functional compound is in an amount of from about 1 wt % to about 25 wt % of the composition.

13. The composition of claim 1, further comprising at least one catalyst.

14. The composition of claim 13, wherein the at least one catalyst is in an amount of from about 0.2 wt % to about 3 wt % of the composition.

15. A dry film, comprising:
a carrier substrate, and
a dielectric film supported by the carrier substrate, wherein the film is prepared from the composition of claim 1.

16. A process for depositing a metal layer, comprising:
a) depositing the composition of claim 1 on a substrate to form a dielectric film;
b) exposing the dielectric film to radiation or heat or a combination of radiation or heat;
c) patterning the dielectric film to form a patterned dielectric film having openings;
d) optionally depositing a seed layer on the patterned dielectric film; and
e) depositing a metal layer in at least one opening in the patterned dielectric film.

17. A process for forming a dielectric film on a substrate, comprising:
a) providing a substrate containing copper conducting metal wire structures that form a network of lines and interconnects on the substrate;
b) depositing the composition of claim 1 on the substrate to form a dielectric film; and
c) exposing the dielectric film to radiation or heat or a combination of radiation and heat.

18. A three dimensional object prepared by the process of claim 16.

19. The object of claim 18, comprising the dielectric film in at least two or three stacks.
